(19) United States
(12) Patent Application Publication
(10) Pub. No.: US 2024/0313177 A1
(43) Pub. Date: Sep. 19, 2024

(54) DISPLAY PANEL AND DISPLAY DEVICE

(71) Applicant: TIANMA ADVANCED DISPLAY TECHNOLOGY INSTITUTE (XIAMEN) CO., LTD., Xiamen (CN)

(72) Inventor: Sitao HUO, Xiamen (CN)

(73) Assignee: TIANMA ADVANCED DISPLAY TECHNOLOGY INSTITUTE (XIAMEN) CO., LTD., Xiamen (CN)

(21) Appl. No.: 18/673,346

(22) Filed: May 24, 2024

(30) Foreign Application Priority Data
Jan. 19, 2024 (CN) 202410081232.8

(51) Int. Cl. H01L 33/58; H01L 25/075; H01L 33/50; H01L 33/52

(52) U.S. Cl. CPC H01L 33/58; H01L 25/0753; H01L 33/502; H01L 33/52

(57) ABSTRACT

A display panel and a display device are provided. The display panel includes: a driving substrate; a light-emitting unit electrically connected to one side of the driving substrate; a lens structure disposed on a side of the light-emitting unit away from the driving substrate; in a direction perpendicular to a plane where the driving substrate is located, the lens structure at least partially overlaps the light-emitting unit. Through the embodiments of the application, the light extraction efficiency of the display panel is improved, the display effect of the display panel is improved, and the power consumption of the display panel is reduced.

This application claims priority to Chinese Patent Application No. 202410081232.8, titled “DISPLAY PANEL AND DISPLAY DEVICE”, filed on Jan. 19, 2024 with the China National Intellectual Property Administration, which is hereby incorporated by reference in its entirety.

### FIELD

The present disclosure relates to the field of displays, and in particular to a display panel and a display device.

### BACKGROUND

With continuous development of science and technology, various display devices have been widely applied in daily life and work, which brings great convenience. The display panel is a core component of the display device, and the display effect of the display panel directly affects viewing experience.

In conventional technologies, light-emitting diode (LED) chips, as light-emitting units in the display panel, have inherent light pattern characteristics, which are close to the Lambert distribution and have little difference on the luminous flux in each direction, resulting in low light extraction efficiency of the display panel at a front-view angle. A large driving current is essential to drive the light-emitting unit to emit light, in order to meet the brightness requirement at the front-view angle for the display panel, which may increase power consumption of the display panel.

### SUMMARY

A display panel and a display device are provided according to embodiments of the present disclosure, in order to solve the foregoing problems. The light extraction efficiency of the display panel is improved, the display effect of the display panel is improved, and the power consumption of the display panel is reduced.

In one embodiment, a display panel is provided according to an embodiment of the present disclosure. The display panel includes: a driving substrate; a light-emitting unit, electrically connected to one side of the driving substrate; a lens structure, disposed on one side of the light-emitting unit away from the driving substrate; where the lens structure at least partially overlaps the light-emitting unit in a direction perpendicular to a plane where the driving substrate is located.

In one embodiment, a display device is provided according to an embodiment of the present disclosure. The display device includes the display panel according to any one of the embodiments.

### BRIEF DESCRIPTION OF THE DRAWINGS

Accompanying drawings, which are incorporated in and constitute a part of this specification, illustrate embodiments of the present disclosure and serve to explain principles of the present disclosure together with the specification.

Hereinafter drawings to be applied in embodiments of the present disclosure are briefly described, in order to clarify illustration of the embodiments of the present disclosure.

FIG. 1 is a schematic cross-sectional structural diagram of a display panel according to an embodiment of the present disclosure.

FIG. 2 is a schematic diagram of lights of the display panel shown in FIG. 1.

FIG. 3 is a schematic cross-sectional structural diagram of a display panel according to another embodiment of the present disclosure.

FIG. 4 is a schematic cross-sectional structural diagram of a display panel according to another embodiment of the present disclosure.

FIG. 5 is a schematic cross-sectional structural diagram of a display panel according to another embodiment of the present disclosure.

FIG. 6 is a schematic cross-sectional structural diagram of a display panel according to another embodiment of the present disclosure.

FIG. 7 is a schematic cross-sectional structural diagram of a display panel according to another embodiment of the present disclosure.

FIG. 8 is a schematic cross-sectional structural diagram of a display panel according to another embodiment of the present disclosure.

FIG. 9 is a schematic cross-sectional structural diagram of a display panel according to another embodiment of the present disclosure.

FIG. 10 is a schematic cross-sectional structural diagram of a display panel according to another embodiment of the present disclosure.

FIG. 11 is a schematic cross-sectional structural diagram of a display panel according to another embodiment of the present disclosure.

FIG. 12 is a schematic cross-sectional structural diagram of a display panel according to another embodiment of the present disclosure.

FIG. 13 is a schematic cross-sectional structural diagram of a display panel according to another embodiment of the present disclosure.

FIG. 14 is a schematic cross-sectional structural diagram of a display panel according to another embodiment of the present disclosure.

FIG. 15 is a schematic cross-sectional structural diagram of a display panel according to another embodiment of the present disclosure.

FIG. 16 is a schematic cross-sectional structural diagram of a display panel according to another embodiment of the present disclosure.

FIG. 17 is a schematic cross-sectional structural diagram of a display panel according to another embodiment of the present disclosure.

FIG. 18 is a schematic cross-sectional structural diagram of a display panel according to another embodiment of the present disclosure.

FIG. 19 is a schematic cross-sectional structural diagram of a display panel according to another embodiment of the present disclosure.

FIG. 20 is a schematic structural diagram of a curved display panel according to an embodiment of the present disclosure.

FIG. 21 is a schematic structural diagram of a curved display panel according to another embodiment of the present disclosure.

FIG. 22 is a schematic structural diagram of a curved display panel according to another embodiment of the present disclosure.

FIG. 23 is a schematic cross-sectional structural diagram of a display panel according to another embodiment of the present disclosure.

FIG. 24 is a schematic cross-sectional structural diagram of a display panel according to another embodiment of the present disclosure.

FIG. 25 is a schematic cross-sectional structural diagram of a display panel according to another embodiment of the present disclosure.

FIG. 26 is a schematic cross-sectional structural diagram of a display panel according to another embodiment of the present disclosure.

FIG. 27 is a schematic cross-sectional structural diagram of a display panel according to another embodiment of the present disclosure.

FIG. 28 is a schematic cross-sectional structural diagram of a display panel according to another embodiment of the present disclosure.

FIG. 29 is a schematic diagram of an optical path of a display panel shown in FIG. 6.

FIG. 30 is a schematic structural diagram of a display device according to an embodiment of the present disclosure.

### REFERENCE NUMERALS

1 driving substrate; 2 light-emitting unit;
3 lens structure; 4 encapsulation structure;
5 filter particle; 6 planarization layer;
21 first color light-emitting unit; 22 second color light-emitting unit;
23 third color light-emitting unit; 201 first light-emitting unit;
202 second light-emitting unit; 203 third light-emitting unit;
31 first lens; 32 second lens;
33 third lens; 34 fourth lens;
35 fifth lens; 36 sixth lens;
37 seventh lens; 301 first lens structure;
302 second lens structure; 50 third color particle;
51 first color particle; 52 second color particle;
53 color conversion particle; 54 transparent particle.

### DETAILED DESCRIPTION

Hereinafter solutions will be further described in order to clarify the foregoing embodiments of the present disclosure. It should be noted that, embodiments of the present disclosure and features in the embodiments can be combined with each other in case of no conflict.

Hereinafter many specific details are set forth to fully understand the present disclosure, the present disclosure may also be implemented in other ways different from those described here. Apparently, the embodiments in the description are only part, not all of the embodiments of the present disclosure.

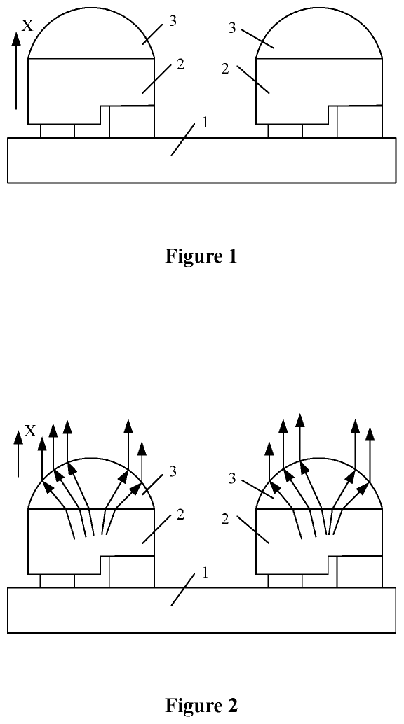

A display panel is provided according to an embodiment of the present disclosure. FIG. 1 is a schematic cross-sectional structural diagram of a display panel according to an embodiment of the present disclosure. FIG. 2 is a schematic diagram of lights of the display panel shown in FIG. 1. Reference is made to FIGS. 1 and 2, the display panel includes: a driving substrate 1; a light-emitting unit 2, electrically connected to one side of the driving substrate 1; a lens structure 3, disposed on one side of the light-emitting unit 2 away from the driving substrate 1; where the lens structure 3 at least partially overlaps the light-emitting unit 2 in a direction X perpendicular to a plane where the driving substrate is located.

Reference is made to FIG. 1, the driving substrate 1 may include a circuit structure for transmitting electrical signals to the light-emitting unit 2 to drive the light-emitting unit 2 to emit light. The light-emitting unit 2 may include a cathode and an anode, which are respectively electrically connected to the driving substrate 1 to form an electrical signal loop between the light-emitting unit 2 and the driving substrate 1, and the light-emitting unit 2 may emit light on a basis of the electrical signals transmitted by the driving substrate 1.

When the light-emitting unit 2 emits light, the amount of light emitted in different directions is not much different due to the light pattern characteristic of Lambert distribution, which results in low light extraction efficiency of the light-emitting unit 2 at the front-view angle. In order to achieve the brightness requirement of the front-view angle, i.e., the direction perpendicular to the driving substrate 1, the driving substrate 1 needs to apply a large driving current to the light-emitting unit 2 to drive the light-emitting unit 2 to emit light, to increase the power consumption of the display panel.

In order to solve this problem, herein a lens structure 3 is disposed on one side of the light-emitting unit 2 away from the driving substrate 1. Arrows in FIG. 2 represents directions of the light. Reference is made to FIG. 2, the lens structure 3 may converge the light to concentrate the light emitted by the light-emitting unit 2 at the front-view light emission angle as much as possible, to increase the light extraction efficiency and improving the display effect of the display panel, to eliminate the need to increase the driving current of the driving substrate 1 in order to achieve brightness at the front-view angle, which can reduce the power consumption of the display panel. FIG. 1 exemplarily shows that the light-emitting unit 2 and the lens structure 3 are completely overlapped in the direction X perpendicular to a plane where the driving substrate is located. In one embodiment, the lens structure 3 may partially overlap with the light-emitting unit 2. It is not limited herein as long as the convergence effect of the lens structure 3 on the scattered light emitted by the light-emitting unit 2 is satisfied.

The light-emitting unit 2 may be an LED chip, specifically a Micro LED chip, a Mini LED chip or other types of LED chips, or may be other types of light-emitting units, which are not limited herein. In one embodiment, the lens structure 3 may be a lens structure 3 of other shapes, and is not limited to the curved surface shape shown in FIGS. 1 and 2. It is not limited herein as long as the lens structure may converge light.

Herein the lens structure 3 is configured to converge the scattered light emitted by the light-emitting unit 2 at a front-view light emission angle, and the light emitted by the light-emitting unit 2 may be emitted in the direction X perpendicular to the driving substrate as much as possible after passing through the lens structure 3, to avoid the problem of low light extraction efficiency at the front-view angle due to the light dispersion caused by the inherent light pattern of the light-emitting unit 2. The light extraction efficiency of the display panel is increased and the display effect of the display panel is improved, to eliminate the need to increase the driving current of the driving substrate 1 in order to achieve the brightness at the front-view angle. The power consumption of the display panel can be reduced.

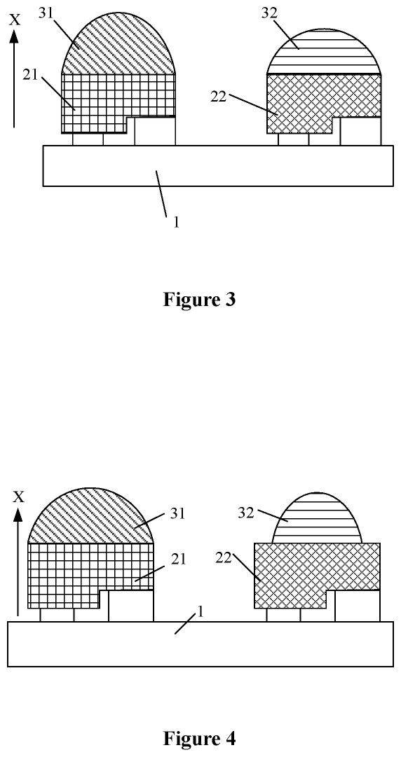

FIG. 3 is a schematic cross-sectional structural diagram of a display panel according to another embodiment of the present disclosure. FIG. 4 is a schematic cross-sectional structural diagram of a display panel according to another embodiment of the present disclosure. In an embodiment, in conjunction with FIGS. 3 and 4, the light-emitting unit 2 includes a first color light-emitting unit 21 and a second color light-emitting unit 22. The first color is different from the second color. The lens structure 3 includes a first lens 31 and a second lens 32. In the direction X perpendicular to the plane of the driving substrate 1, the first lens 31 overlaps the first color light-emitting unit 21, the second lens 32 overlaps the second color light-emitting unit 22. The first lens 31 and second lens 32 are different from each other in at least one of curvature, refractive index, and width in a preset direction parallel to a plane the driving substrate 1.

Reference is made to FIGS. 3 and 4, different filling patterns are configured to distinguish the first color light-emitting unit 21 and the second color lighting unit 22, and different filling patterns are configured to distinguish the first lens 31 and the second lens 32.

As the wavelength of light increases, the refractive index increases according to optical principles. That is, when the light passes through a same medium at a same incident angle, the refraction angle of the light with a longer wavelength is smaller than the refraction angle of the light with a shorter wavelength. Since the wavelength of the first color light emitted by the first color light-emitting unit 21 is different from the second color light emitted by the second color light-emitting unit 22, the refraction angle of the first color light is different from the refraction angle of the second color light, which results in different light amounts of the first color light and the second color light at the front-view angle. In order to ensure that the light-emitting units 2 of different colors emit the same amount of light as possible, the first lens 31 and the second lens 32 need to be set differentially.

Due to different curvatures of the first lens 31 and the second lens 32, the first lens 31 and the second lens 32 have different light converging effects. When the first lens 31 and the second lens 32 have different refractive indexes, the first lens 31 and the second lens 32 have light converging effects. When the first lens 31 and the second lens 32 have different widths in the preset direction parallel to the plane the driving substrate 1, the first lens 31 and the second lens 32 have different light converging effects. Therefore, at least one of the curvature, refractive index, and width in a preset direction parallel to the plane of the driving substrate 1 of the first lens 31 may be set to be different from that of the second lens 32 to balance the amount of light emitted by the first color light-emitting unit 21 and the second color light-emitting unit 22 at the front-view angle to avoid the problem of color deviation on the display panel.

FIG. 3 shows that the first lens 31 and the second lens 32 have different curvatures. FIG. 4 shows that the first lens 31 and the second lens 32 have different widths in the preset direction parallel to a plane where the driving substrate 1 is located.

In an embodiment, the refractive index of the first lens 31 is smaller than the refractive index of the second lens 32.

In an embodiment, the wavelength of the first color light emitted by the first color light-emitting unit 21 is greater than the wavelength of the second color light emitted by the second color light-emitting unit 22. Based on the optical principle, n=C/λ, where n represents a refractive index, C represents a wavelength of light, λ represents frequency of light. When the frequency of light is the same, the longer the wavelength of light is, the greater the refractive index of light is. Therefore, the refractive index of the first color light is greater than the refractive index of the second color light. When the light passes through the same medium at the same incident angle, according to the refractive index formula, the refractive index n=sin α/sin β, where a is an incident angle and β is a refraction angle. The refraction angle of the first color light is smaller than the refraction angle of the second color light. In order to balance the amount of the first color light and the second color light emitted at the front-view angle, it is necessary to increase the refraction angle of the first color light and reduce the refraction angle of the second color light. Therefore, when the incident angles of the first color light and the second color light are the same, according to the refractive index formula, the refractive index of the first lens 31 may be set to be smaller than the refractive index of the second lens 32.

In an embodiment, the first color light-emitting unit 21 is, e.g., a red light-emitting unit 2, the second color light-emitting unit 22 is, e.g., a green light-emitting unit 2. Based on the optical principle, the wavelength of the red light ranges from 620 nm to 750 nm, the wavelength of the green light ranges from 495 nm to 570 nm. Therefore, the wavelength of red light emitted by the red light-emitting unit 2 is greater than the wavelength of green light emitted by the green light-emitting unit 2. The refractive index of red light is greater than the refractive index of green light, and the refractive angle of red light is smaller than the refractive angle of green light. Therefore, the amount of red light emitted at the front-view angle may be different from the amount of green light emitted at the front-view angle, which results in color deviation on the display panel. In order to balance the amount of red light and green light emitted at the front-view angle, the refractive index of the first lens 31 overlapping the red light-emitting unit 2 is smaller than the refractive index of the second lens 32 overlapping the green light-emitting unit 2. That is, when incident angles of red light and green light are the same, the refraction angle of red light is increased and the refraction angle of green light is decreased, to increase the amount of red light emitted at front-view angles and reducing the amount of green light emitted at front-view angles. The effect of balancing the amount of red light and green light emitted at front-view angles is achieved and the color deviation is avoided.

The first color light-emitting unit 21 may be, e.g., a red light-emitting unit 2, and the second color light-emitting unit 22 may be, e.g., a blue light-emitting unit 2. The wavelength of blue light ranges from 450 nm to 495 nm, the wavelength of the red light emitted by the red light-emitting unit 2 is greater than the wavelength of the blue light emitted by the blue light-emitting unit 2. The refractive index of the red light is greater than the refractive index of the blue light. The refraction angle of the red light is smaller than the refraction angle of the blue light. Therefore, there is a difference in the amount of the red light emitted at the front-view angle, resulting in color deviation on the display panel. In order to balance the amount of red light and blue light emitted at the front-view angle, the refractive index of the first lens 31 overlapping the red light-emitting unit 2 is smaller than the refractive index of the second lens 32 overlapping the blue light-emitting unit 2. That is, when the incident angles of the red light and the blue light are the same, the refraction angle of red light is increased and the refraction angle of blue light is decreased, to increase the amount of red light emitted at front-view angles and reducing the amount of blue light emitted at front-view angles, achieving the effect of balancing the amount of the red light and the blue light emitted at the front-view angle to avoid color deviation.

In an embodiment, the first color light-emitting unit 21 may be, e.g., a green light-emitting unit 2, the second color light-emitting unit 22 may be, e.g., a blue light-emitting unit 2. A wavelength of the green light emitted by the green light-emitting unit 2 is greater than the wavelength of the blue light emitted by the blue light-emitting unit 2. The refractive index of green light is greater than the refractive index of blue light, and the refractive angle of green light is smaller than the refractive angle of blue light. Therefore, there will be a difference between the amount of green light emitted at the front-view angle and the amount of blue light emitted at the front-view angle, resulting in color deviation on the display panel. In order to balance the amount of green light and blue light emitted at the front-view angle, the refractive index of the first lens 31 overlapping the green light-emitting unit 2 is smaller than the refractive index of the second lens 32 overlapping the blue light-emitting unit 2. That is, when the incident angles of the green light and blue light are the same, the refraction angle of the green light is increased and the refraction angle of the blue light is reduced, to increase the amount of the green light emitted at front-view angle and reducing the amount of the blue light emitting at front-view angle to achieve the effect of balancing the amount of the green light and the blue light emitted at the front-view angle to avoid color deviation.

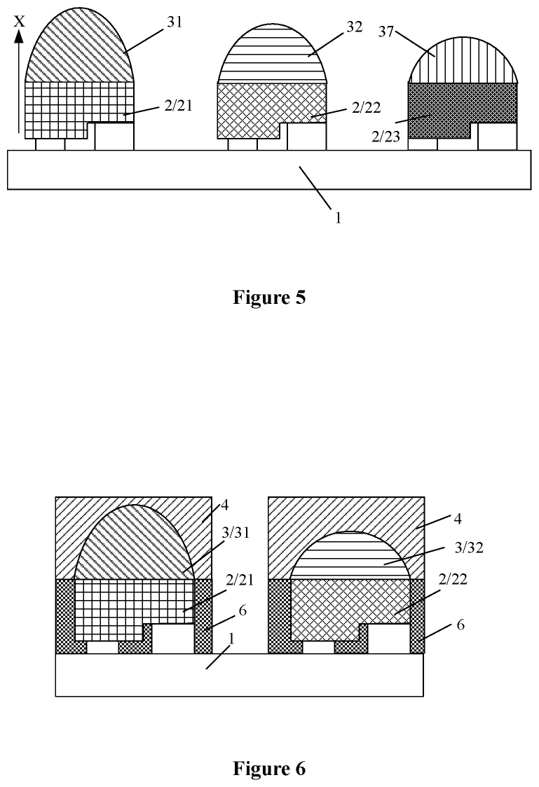

FIG. 5 is a schematic cross-sectional structural diagram of a display panel according to another embodiment of the present disclosure. Reference is made to FIG. 5, the light-emitting unit 2 includes a first color light-emitting unit 21, a second color light-emitting unit 22 and a third color light-emitting unit 23. The first color, the second color and the third color are different. The lens structure 3 includes a first lens 31, a second lens 32 and a seventh lens 37. In a direction X perpendicular to the plane of the driving substrate 1, the first lens 31 overlaps the first color light-emitting unit 21, and the second lens 32 overlaps the second color light-emitting unit 22, the seventh lens 37 overlaps the third color light-emitting unit 23.

In an embodiment, the first color light is, e.g., red light, the second color light is, e.g., green light, and the third color light is, e.g., blue light. The wavelength of red light is greater than the wavelength of green light, and the wavelength of green light is greater than the wavelength of blue light. The refractive index of red light is greater than that of green light. The refractive index of green light is greater than that of blue light. The refractive angle of red light is smaller than that of green light. The refractive angle of green light is smaller than that of blue light. Therefore, there will be a difference between the amount of red light, green light and blue light emitted at the front-view angle, resulting in color deviation on the display panel. In order to balance the amount of red light, green light and blue light emitted at front-view angle, the refractive index of the first lens 31 is smaller than the refractive index of the second lens 32 and the refractive index of the second lens 32 is smaller than the refractive index of the seventh lens 37. That is, when the incident angles of the red light, the green light and the blue light are the same, the refraction angle of red light is increased, the refraction angles of the green light and the blue light are decreased, to increase the amount of red light emitted at the front-view angle and reducing the amount of the green light and the blue light at the front-view angle to achieve the effect of balancing the amount of red light, green light and blue light emitted at the front-view angle and avoid color deviation.

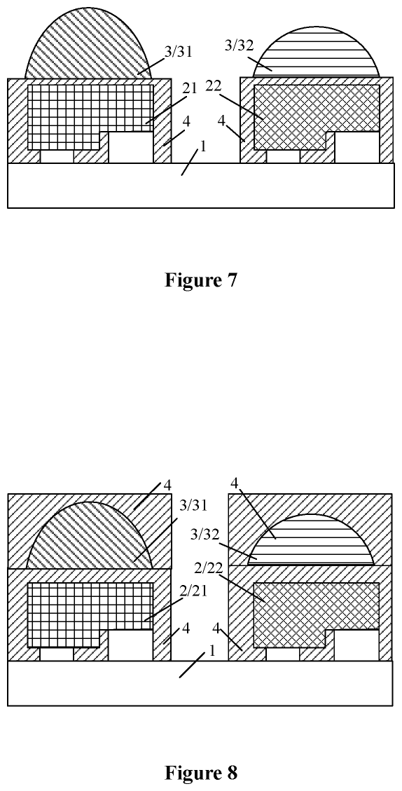

FIG. 6 is a schematic cross-sectional diagram of a display panel according to another embodiment of the present disclosure. FIG. 7 is a schematic cross-sectional diagram of a display panel according to another embodiment of the present disclosure. FIG. 8 is a schematic cross-sectional diagram of a display panel according to another embodiment of the present disclosure. In an embodiment, reference is made to FIGS. 6 to 8, the display panel further includes: an encapsulation structure 4, located at least on one side of the lens structure 3 away from the light-emitting unit 2, and/or between the lens structure 3 and the light-emitting unit 2; where the refractive index difference between the first lens 31 and the encapsulation structure 4 is smaller than the refractive index difference between the second lens 32 and the encapsulation structure 4.

In an embodiment, reference is made to FIGS. 6 to 8, the encapsulation structure 4 may further be provided in the display panel. The encapsulation structure 4 is configured to protect the light-emitting unit 2 from corrosion by water or oxygen in the external environment, and improve the reliability of the light-emitting unit 2. FIG. 6 shows that the encapsulation structure 4 is located on one side away from the light-emitting unit 2, and a planarization layer 6 is disposed on one side of the encapsulation structure 4 facing the driving substrate 1. FIG. 7 shows that the encapsulation structure 4 is located between the lens structure 3 and the light-emitting unit 2. FIG. 8 shows that the encapsulation structure 4 is located on one side of the lens structure 3 away from the light-emitting unit 2, and is located between the lens structure 3 and the light-emitting unit 2. The encapsulation structure 4 may also play a role of planarization through disposing the encapsulation structure 4 between the lens structure 3 and the light-emitting unit 2, and provides a flat surface for the lens structure 3 and facilitates the production of the lens structure 3.

Reference is made to FIGS. 6 to 8, the first color light is emitted from the first color light-emitting unit 21 through the first lens 31 and the encapsulation structure 4, and the second color light is emitted from the second color light-emitting unit 22 through the second lens 32 and the encapsulation structure 4. Since the wavelength of the first color light is, e.g., greater than the wavelength of the second color light, the refractive index of the first color light is greater than the refractive index of the second color light, the amount of the first color light emitted at front-view angle is different from the amount of the second color light emitted at front-view angle. In order to solve this problem, the refractive index difference between the first lens 31 and the encapsulation structure 4 may be set to be smaller than the refractive index difference between the second lens 32 and the encapsulation structure 4, to increase the refraction angle of the first color light and reduce the refraction angle of the second color light, to increase the amount of the first color light emitted at the front-view angle, reducing the amount of the second color light emitted at the front-view angle, to achieve the effect of balancing the amount of the first color light and the second color light emitted at the front-view angle.

The first color light may be set to red light and the second color light may be set to green light, or the first color light may be set to red light and the second color light may be set to blue light, or the first color light may be set to green light, the second color light may be blue light, which is not limited herein.

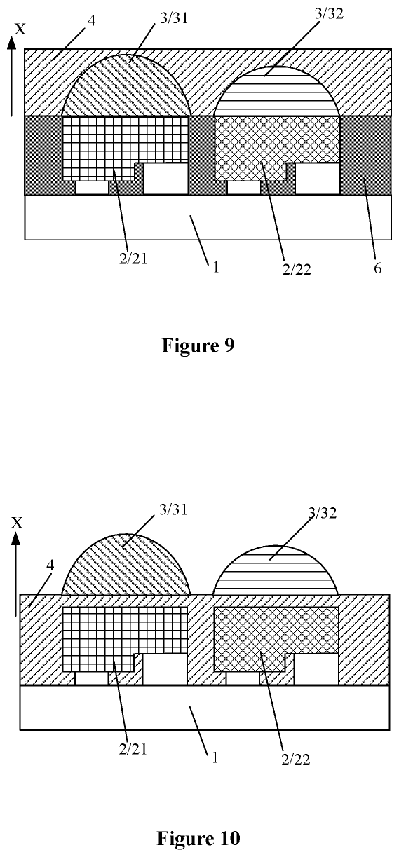

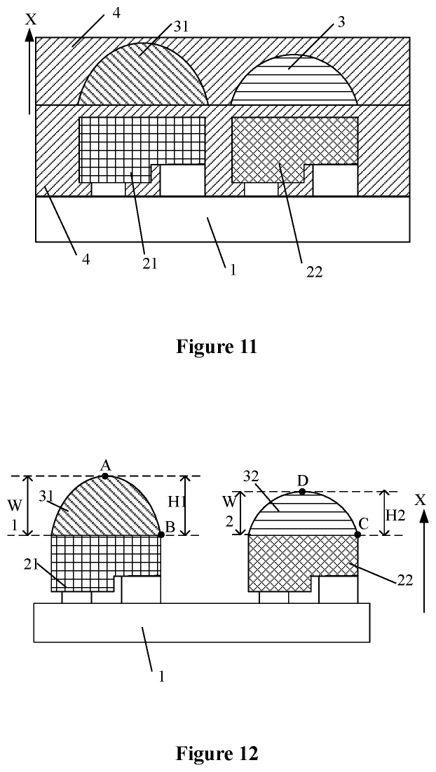

FIG. 9 is a schematic cross-sectional structural diagram of a display panel according to another embodiment of the present disclosure. FIG. 10 is a schematic cross-sectional structural diagram of a display panel according to another embodiment of the present disclosure. FIG. 11 is a schematic cross-sectional structural diagram of a display panel according to another embodiment of the present disclosure. In an embodiment, reference is made to FIGS. 9 to 11, the encapsulation structure 4 overlapping the light-emitting units 2 of different colors is provided integrally in the direction X perpendicular to the plane where the driving substrate 1 is located.

Reference is made to FIGS. 9 to 11, the encapsulation structure 4 may further be integrated in the direction X perpendicular to the plane where the driving substrate 1 is located. The encapsulation structure 4 encapsulates the light-emitting unit 2 and the lens structure 3 as a whole, there is no need to set the encapsulation structure 4 in a one-to-one correspondence with the first lens 31 or the second lens 32, which simplifies the preparation process of the encapsulation structure 4 and improves encapsulation efficiency.

FIG. 9 shows that the encapsulation structure 4 is integrally disposed on one side away from the light-emitting unit 2, and shows that a planarization layer 6 is disposed on one side of the encapsulation structure 4 facing the driving substrate 1. FIG. 10 shows that the encapsulation structure 4 is integrally disposed between the lens structure 3 and the light-emitting unit 2. FIG. 11 shows that the encapsulation structure 4 is integrally disposed on one side of the lens structure 3 away from the light-emitting unit 2, and is integrally disposed between the lens structure 3 and the light-emitting unit 2.

FIG. 12 is a schematic cross-sectional structural diagram of a display panel according to an embodiment of the present disclosure. In an embodiment, reference is made to FIG. 12, in the direction X perpendicular to the plane of the driving substrate 1, there is a first height difference H1 between a first position B and a second position A of the first lens 31, there is a second height difference H2 between a third position C and a fourth position D of the second lens 32, the first height difference H1 is greater than the second height difference H2; where the first position B is disposed between the second position A and the edge of the first lens 31, the third position C is disposed between the fourth position D and the edge of the second lens 32. In a same direction parallel to the plane where the driving substrate 1 is located, a distance between the first position B and the second position A is equal to the distance between the third position C and the fourth position D, the distance between the first position B and the edge of the first lens 31 is equal to the distance between the third position C and the edge of the second lens 32, and/or the distance between the second position A and the edge of the first lens 31 is equal to the distance between the fourth position D and the edge of the second lens 32.

In an embodiment, the first position B may be the edge of the first lens 31 as shown in FIG. 12, the second position A may be the center of the first lens 31 as shown in FIG. 12, the third position C may be the edge of the second lens 32 as shown in FIG. 12, and the fourth position D may be the center of the second lens 32 as shown in FIG. 2. In the direction X perpendicular to the plane of the driving substrate 1, the first height difference H1 between the center A and the edge B of the first lens 31 is greater than the second height difference H2 between the center D and the edge C of the second lens 32, and the curvature of the first lens 31 is greater than the curvature of the second lens 32. When the curvature of the lens increases, the refraction angle of the light may also increase, to increase the refraction angle of the first color light and reducing the refraction angle of the second color light, to increase the amount of the first color light emitted at the front-view angle and reducing the amount of the second color light emitted at the front-view angle, to achieve an effect of balancing amounts of the first color light and the second color light emitted at the front-view angle to avoid color deviation.

FIG. 12 is only an embodiment of the first position B, the second position A, the third position C and the fourth position D. The first position B and the second position A may be any two positions of the first lens 31 as long as the first position B is located between the second position A and the edge of the first lens 31. The third position C and the fourth position D may be any two positions of the second lens 32 as long as the third position C is located between the fourth position D and the edge of the second lens 32.

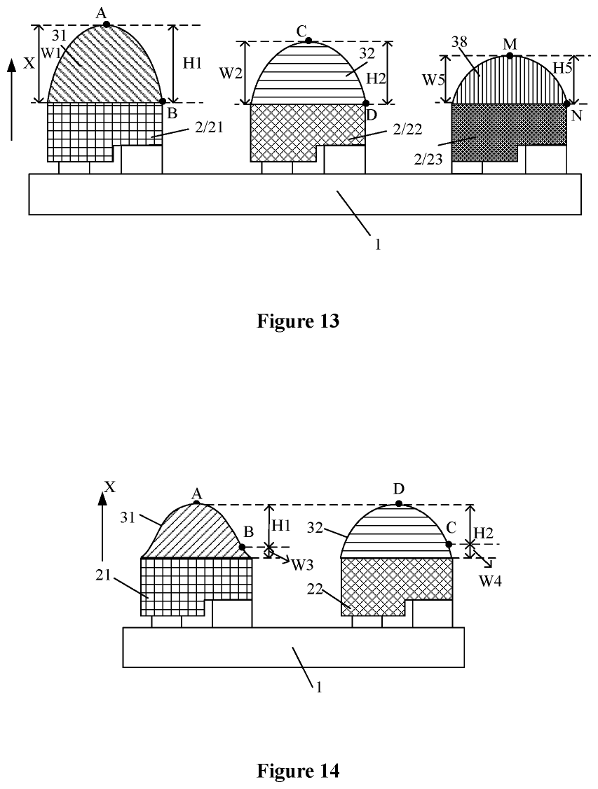

FIG. 13 is a schematic cross-sectional structural diagram of a display panel according to an embodiment of the present disclosure. In an embodiment, as shown in FIG. 13, the light-emitting unit 2 includes a first color light-emitting unit 21, a second color light-emitting unit 22 and a third color light-emitting unit 23, where the first color, the second color and the third color are different. The lens structure 3 includes a first lens 31, a second lens 32 and an eighth lens 38. In the direction X perpendicular to the plane of the driving substrate 1, the first lens 31 overlaps the first color light-emitting unit 21, the second lens 32 overlaps the second color light-emitting unit 22, the eighth lens 38 overlaps the third color light-emitting unit 23.

In an embodiment, the first position B may be the edge of the first lens 31 as shown in FIG. 13, the second position A may be the center of the first lens 31 as shown in FIG. 13, the third position C may be the edge of the second lens 32 as shown in FIG. 12, the fourth position D may be the center of the second lens 32 as shown in FIG. 2, the ninth position M may be the edge shown in FIG. 12, and the tenth position N may be the center shown in FIG. 13. In the direction X perpendicular to the plane of the driving substrate 1, the first height difference H1 between the center A and the edge B of the first lens 31 is greater than the second height difference H2 between the center D and the edge C of the second lens 32, and the second height difference H2 is greater than the fifth height difference H5 between the center N and the edge M of the eighth lens 38, and the curvature of the first lens 31 is greater than the curvature of the second lens 32, and the curvature of the second lens 32 is greater than the curvature of the eighth lens 38. When the curvature of the lens increases, the refraction angle of the light may also increase, which can increase the refraction angle of the first color light and reduce the refraction angles of the second color light and the third color light, to increase the amount of the first color light emitted at front-view angle and reducing the amount of the second color light and the third color light emitted at the front-view angle, to achieve the effect of balancing amounts of the first color light, the second color light and the third color light emitted at the front-view angle, and avoid color deviation.

FIG. 13 is only an embodiment of the first position B, the second position A, the third position C, the fourth position D, the ninth position M and the tenth position N. The first position B and the second position A may be any two positions of the first lens 31, as long as the first position B is located between the second position A and the edge of the first lens 31. The third position C and the fourth position D may be any two positions of the second lens 32 as long as the third position C is located between the fourth position D and the edge of the second lens 32. The ninth position M and the tenth position N may be any two positions of the eighth lens 38 as long as the ninth position M is located between the tenth position N and the edge of the eighth lens 38.

In one embodiment, as shown in FIG. 12, in a plane parallel to the plane of the driving substrate 1, a projection of the first lens 31 is equal to the projection of the second lens 32. On a basis of a same projection, the first height difference H1 is greater than the second height difference H2, and the curvature of the first lens 31 is greater than the curvature of the second lens 32, the refraction angle of the first color light is increased and the refraction angle of the second color light is decreased. In one embodiment, the amount of the first color light emitted at the front-view angle is increased, and the amount of the second color light emitted at the front-view angle is reduced, to achieve the effect of balancing amounts of the first color light and the second color light emitted at the front-view angle. In an embodiment, the first color light is, e.g., red light, and the second color light is, e.g., green light, or the first color light is red light, and the second color light is blue light, or the first color light is green light, and the second color light is blue light.

In one embodiment, as shown in FIG. 13, in a plane parallel to the plane of the driving substrate 1, projections of the first lens 31, the second lens 32 and the eighth lens 38 are the same. On a basis of a same projection, a first height difference H1 may be greater than the second height difference H2, and the second height difference H2 is greater than the fifth height difference H5, and the refractive index and curvature of the first lens 31 is greater than the curvature of the second lens 32, and the curvature of the second lens 32 is greater than the curvature of the eighth lens 38, the refraction angle of the first color light is increased, the refraction angles of the second color light and the third color light are reduced, to increase the amount of the first color light emitted at the front-view angle, and reducing amounts of the second color light and the third color light emitted at the front-view angle, to achieve the effect of balancing the amounts of the first color light, the second color light and the third color light emitted at the front-view angle, and avoid color deviation. In an embodiment, the first color light is red light, the second color light is green light, and the third color light is blue light.

The same projection in the foregoing embodiment refers to the same within an error range of the manufacturing process. For example, the difference between the projection of the first lens 31 and the projection of the second lens 32 does not exceed 5%. The projections mentioned in subsequent embodiments being the same may be understood in the same way, which will not be described again in subsequent embodiments.

FIG. 14 is a schematic cross-sectional structural diagram of a display panel according to an embodiment of the present disclosure. In an embodiment, in conjunction with FIGS. 13 and 14, in the direction X perpendicular to the plane of the driving substrate 1, the thickness W1 of the first lens 31 at the second position A is greater than the thickness W2 of the second lens 32 at the fourth position D; and/or, the thickness W3 of the first lens 31 at the first position B is smaller than the thickness W4 of the second lens 32 at the third position C.

In an embodiment, reference is made to FIG. 13, in the direction X perpendicular to the plane of the driving substrate 1, when the height of the first lens 31 at the first position B is equal to the height of the second lens 32 at the third position C, the thickness W1 of the first lens 31 at the second position A is greater than the thickness W2 of the second lens 32 at the fourth position D, and the height difference H1 between the first position B and the second position A of the first lens 31 is greater than the height difference H2 between the third position C and the fourth position D of the second lens 32, and the curvature of the first lens 31 is greater than the curvature of the second lens 32. When the curvature of the lens increases, the refraction angle of the light may also increase, to increase the amount of the first color light emitted at the front-view angle and reducing the amount of the second color light emitted at the front-view angle, to achieve the effect of balancing amounts of the first color light and the second color light emitted at the front-view angle.

In an embodiment, reference is made to FIG. 14, in the direction X perpendicular to the plane of the driving substrate 1, when the height of the first lens 31 at the second position is equal to the height of the second lens 32 at the fourth position D, the thickness W3 of the first lens 31 at the first position B is smaller than the thickness W4 of the second lens 32 at the third position C, to increase the refraction angle of the first color light and reduce the refraction angle of the second color light, thereby, the amount of the first color light emitted at the front-view angle is increased, and the amount of the second color light emitted at the front-view angle is reduced, thereby achieving the effect of balancing the amounts of red light and green light emitted at the front-view angle.

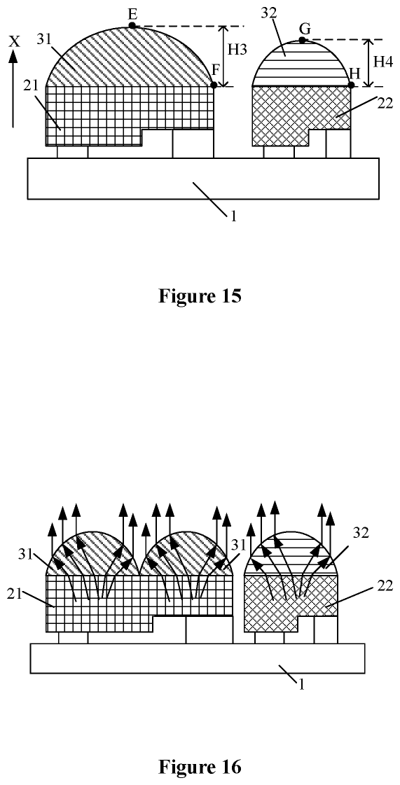

FIG. 15 is a schematic cross-sectional structural diagram of a display panel according to another embodiment of the present disclosure. FIG. 16 is a schematic cross-sectional structural diagram of a display panel according to another embodiment of the present disclosure. In an embodiment, reference is made to FIGS. 15 and 16, in a plane parallel to the plane where the drive substrate 1 is located, the projection of the first color light-emitting unit 21 is larger than the projection of the second color light-emitting unit 22. In the plane parallel to the plane where the drive substrate 1 is located, the projection of the first lens 31 is greater than the projection of the second lens 32; and/or, the number of the first lenses 31 overlapping a same first color light-emitting unit 21 is greater than the number of the second lenses 32 overlapping a same second color light-emitting unit 22.

In an embodiment, reference is made to FIGS. 15 and 16, the first color light-emitting unit 21 is, e.g., a red light-emitting unit 2, which has low light extraction efficiency. Therefore, in a plane parallel to the plane where the driving substrate 1 is located, the projection of the first color light-emitting unit 21 is larger than the projection of the second color light-emitting unit 22. The brightness of the first color light-emitting unit 21 can be increased through increasing the projection of the first color light-emitting unit 21.

In an embodiment, in order to realize the adjustment of the light emission angle of the first color light-emitting unit 21 by the first lens 31, the projection of the first lens 31 may be larger than the projection of the second lens 32, as shown in FIG. 15. Reference is made to FIG. 15, the first lens 31 completely overlaps the first color light-emitting unit 21, the second lens 32 completely overlaps the second color light-emitting unit 22, and the light emitted by the first color light-emitting unit 21 is converged to a front-view light emitting angle through the first lens 31 and emitted, the light emitted by the second color light-emitting unit 22 is converged to a front light emitting angle through the second lens 32 and emitted. The first lens 31 with an enlarged projection has an increased ability to collect light emitted by the first color light-emitting unit 21, thus more light collected may increase the brightness of the first color light-emitting unit 21 at a front-view angle. In addition, full coverage of the first color light-emitting unit 21 can be achieved through setting the projection of the first lens 31 to be larger than the projection of the second lens 32, and the light emitted by the first color light-emitting unit can be concentrated as much as possible to improve the utilization of light.

In an embodiment, since the projection of the first color light-emitting unit 21 is larger than the projection of the second color light-emitting unit 22, the number of the first lenses 31 overlapping a same first color light-emitting unit 21 may be larger than the number of the second lenses 32 overlapping the second color light-emitting unit 22. FIG. 16 shows that the number of first lenses 31 is, e.g., two, the number of second lenses 32 is, e.g., one. Two first lenses 31 converges the light emitted by the first color light-emitting unit 21, to increase the amount of light emitted by the first color light-emitting unit 21 at the front-view angle, and avoiding the problem of low light output of the first color light due to the low light emitting efficiency of the first color light-emitting unit 21.

Herein the number of first lenses 31 and the number of second lenses 32 are not limited, as long as the number of first lenses 31 is greater than the number of second lenses 32.

In an embodiment, as shown in FIG. 15, in a plane parallel to the plane where the driving substrate 1 is located, the projection of the first lens 31 is larger than the projection of the second lens 32; in the direction X perpendicular to the plane of the driving substrate 1, there is a third height difference between the fifth position and the sixth position of the first lens 31, there is a fourth height difference between the seventh position and the eighth position of the second lens 32, and the third height difference H3 is greater than the fourth height difference H4; where the fifth position F is located between the sixth position E and the edge of the first lens 31, the seventh position H is located between the eighth position G and the edge of the second lens 32. In a same direction parallel to a plane where the driving substrate 1 is located, the distance between the fifth position F and the sixth position E is equal to the distance between the seventh position H and the eighth position G. The distance between the fifth position F and the edge of the first lens 31 is equal to the distance between the seventh position H and the edge of the second lens 32, and/or the distance between the sixth position E and the edge of the first lens 31 is equal to the distance between the eighth position G and the edge of the second lens 32.

Reference is made to FIG. 15, the projection of the first lens 31 may be set to be larger than the projection of the second lens 32. For example, the first lens 31 may completely overlap with the first color light-emitting unit 21. That is, a first lens 31 is provided on one side of the first color light-emitting unit 21 away from the driving substrate 1. The sixth position E of the first lens 31 is, e.g., the center of the first lens 31, the fifth position F of the first lens 31 is, e.g., the edge of the first lens 31, and the eighth position G of the second lens 32 is, e.g., the center, the seventh position H of the second lens 32 is, e.g., an edge. The height difference between the center and the edge of the first lens 31 is greater than the height difference between the center and the edge of the second lens 32. That is, the third height difference H3 is greater than the fourth height difference H4, and the ability of the first lens 31 to gather the light emitted by the first color light-emitting unit 21 is increased, and more light can be gathered, to increase the amount of light emitted by the first color light-emitting unit 21 at the front-view angle.

FIG. 15 is only an embodiment of the sixth position E, the fifth position F, the seventh position H and the eighth position G. The sixth position E and the fifth position F may be any two positions of the first lens 31 as long as the fifth position F may be disposed between the sixth position E and the edge of the first lens 31. The seventh position H and the eighth position G may be any two positions of the second lens 32 as long as the seventh position H is disposed between the eighth position G and the edge of the second lens 32.

In an embodiment, as shown in FIG. 16, the number of first lenses 31 overlapping a same first color light-emitting unit 21 is greater than the number of second lenses 32 overlapping a same second color light-emitting unit 22. The curvature of the first lens 31 is equal to the curvature of the second lens 32, and the projections of two in the plane parallel to the plane of the driving substrate 1 are the same.

In an embodiment, as shown in FIG. 16, since the projection of the first color light-emitting unit 21 is larger than the projection of the second color light-emitting unit 22, the number of the first lens 31 overlapping a same first color light-emitting unit 21 may be greater than the number of second lenses 32 overlapping the same second color light-emitting unit 22. Since the curvature of the first lens 31 is same as the curvature of the second lens 32, and the projections of the two in a plane parallel to the plane where the driving substrate 1 is located are the same, the first lens 31 and the second lens 32 may be manufactured through a same process without adding additional manufacturing processes, which simplifies the manufacturing process of the first lens 31 and improves the manufacturing efficiency.

FIG. 16 shows that two first lenses 31 converge the light emitted by the first color light-emitting unit 21. The edge of the first lens 31 is disposed on the first color light-emitting unit 21 without affecting the light condensing effect.

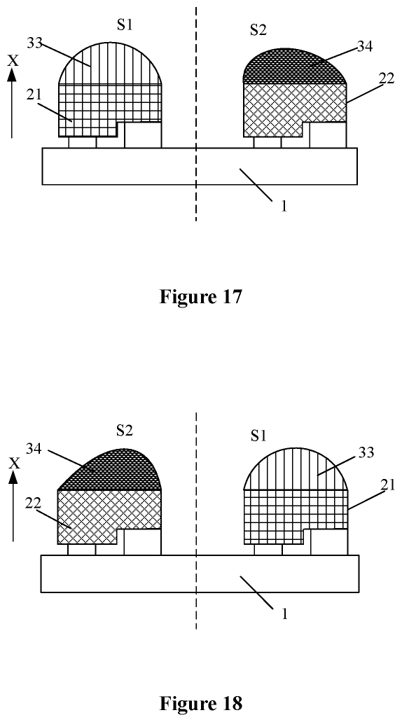

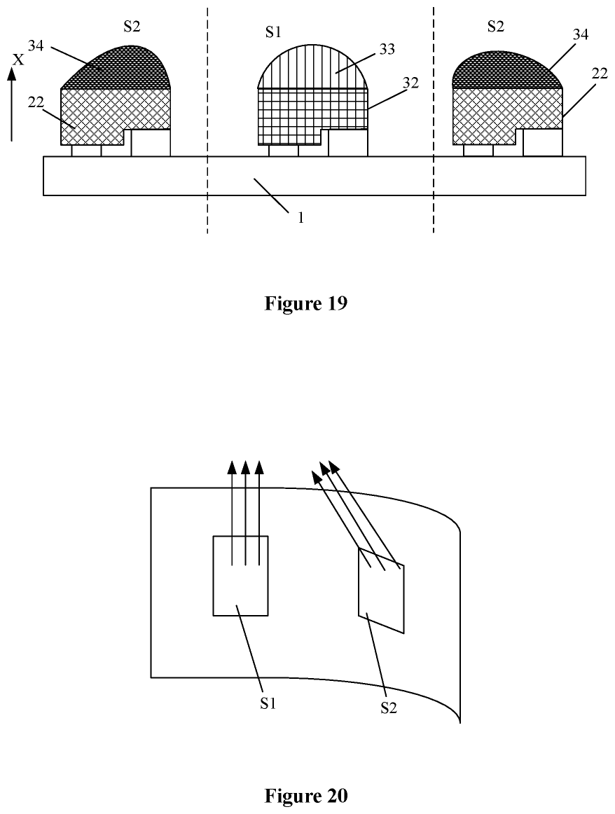

FIG. 17 is a schematic cross-sectional structural diagram of a display panel according to another embodiment of the present disclosure. FIG. 18 is a schematic cross-sectional structural diagram of a display panel according to another embodiment of the present disclosure. FIG. 19 is a schematic cross-sectional structural diagram of a display panel according to another embodiment of the present disclosure. In an embodiment, reference is made to FIGS. 17 to 19, the display panel includes a first area S1 and a second area S2, and the second area S2 is located on at least one side of the first area S1. The lens structure 3 includes a third lens 33 and a fourth lens 34. In the direction X perpendicular to the plane of the driving substrate 1, the third lens 33 overlaps the first area S1, and the fourth lens 34 overlaps the second area S2; a focus of the fourth lens 34 leans toward the first area S1.

In an embodiment, reference is made to FIGS. 17 to 19, the focus of the fourth lens 34 is set to be biased toward the first area S1 and enough light may be converged on the first area S1 to meet the brightness requirements of the first area S1 and to ensure that the display effect of the first area S1.

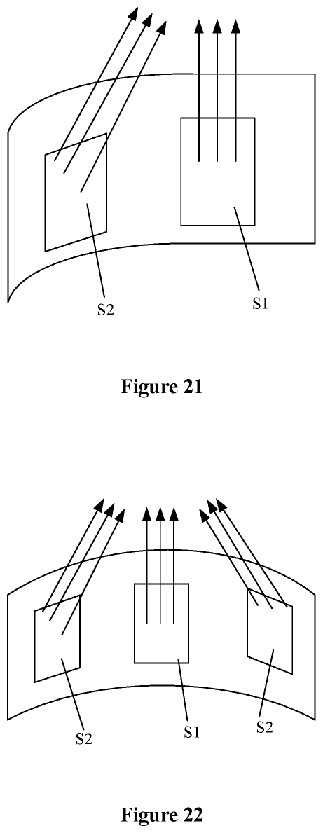

FIG. 20 is a schematic structural diagram of a curved display panel according to an embodiment of the present disclosure. FIG. 21 is a schematic structural diagram of a curved display panel according to another embodiment of the present disclosure. FIG. 22 is a schematic structural diagram of a curved display panel according to another embodiment of the present disclosure. In some embodiments, referring to FIGS. 17 to 22, when the display panel is a curved panel, the first area S1 is, e.g., the front light emitting region of the display panel, that is, a flat region, and the second area S2 is, e.g., the curved region of the display panel. In order to ensure the light extraction efficiency of the first area S1, an intersection point of the fourth lens 34 may be set to be biased toward the first area S1, and the light from the second area S2 converges on the first area S1, i.e., the front light emitting region. In an embodiment, reference is made to FIGS. 17 and 20, when the second area S2 is located on right side of the first area S1, the focus of the fourth lens 34 may be set to the left side. Reference is made to FIGS. 18 and 21, when the second area S2 is located on the left side of the first area S1, the focus of the fourth lens 34 may be set to the right side. As a result, the light extraction efficiency of the first area S1 is increased, and the display effect of the display panel is improved.

Reference is made to FIGS. 19 and 22, the first area S1 is located in the middle position, and the second area S2 is disposed on both sides of the first area S1. The focus of the fourth lens 34 in the second area S2 located on the left side of the first area S1 leans toward the right side, the focus of the fourth lens 34 in the second area S2 located on the right side of the first area S1 leans toward the left side, and the light emitted from the second area S2 on both sides of the first area S1 converges on the first area S1, the brightness of the first area S1 is increased.

FIGS. 20 to 22 exemplarily show a distribution of light emitted from the first area S1 and the second area S2. The light emitted from the second area S2 can be converged on the first area S1 through adjusting the focus position of the fourth lens 34 to increase the brightness of the first area S1.

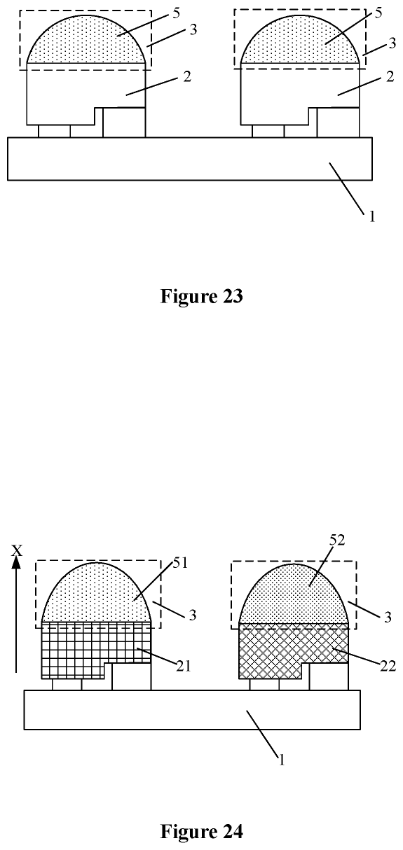

FIG. 23 is a schematic cross-sectional structural diagram of a display panel according to another embodiment of the present disclosure. In an embodiment, as shown in FIG. 23, the lens structure 3 includes a base material structure and filter particles 5, and the filter particles 5 are dispersed in the base material structure.

Since the light-emitting unit 2 is made of, e.g., gallium-containing nitride, the refractive index of which is greater than 2.0, while the refractive index of air is 1.0, the difference in refractive indexes between the air and the light-emitting unit 2 may cause the reflectivity of the light-emitting interface of the light-emitting unit 2 to be high, which in turn causes the light-emitting unit 2 to reflect ambient light, and the metal film layer in the driving substrate 1 to reflect the light emitted by the light-emitting unit 2, to affect the user's viewing of the display screen.

Reference is made to FIG. 23, in order to solve the above problem, herein the filter particles 5 are dispersed in the base material structure of the lens structure 3. The filter particles 5 are configured to absorb the ambient light incident on the display panel and the ambient light reflected by the light-emitting unit 2, are configured to reduce the interface reflectivity of the light-emitting unit 2, and are integrated with the lens structure 3. The lens structure 3 is configured to converge the light from the front-view angle, to improve the performance of the display panel. On the basis of the display effect, the overall structure of the display panel is also simplified. There is no need to arrange a separate space for the filter particles 5, which avoids the problem that the filter particles 5 is arranged separately from the lens structure 3 and occupying too much space on the display panel, which is beneficial to making the display device lighter and thinner.

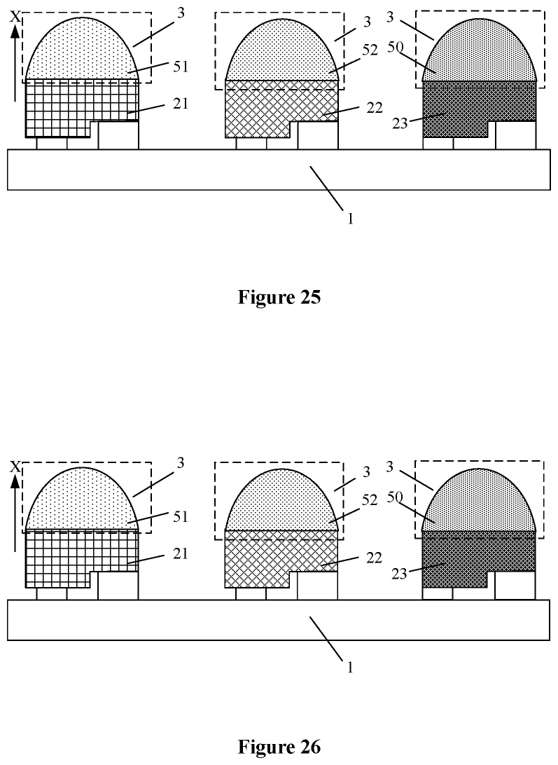

FIG. 24 is a schematic cross-sectional structural diagram of a display panel according to another embodiment of the present disclosure. In an embodiment, as shown in FIG. 24, the light-emitting unit 2 includes a first color light-emitting unit 21 and a second color light-emitting unit 22. The filter particles 5 at least include first color particles 51 and second color particles 52. In the direction X perpendicular to the plane where the driving substrate is located, the lens structure 3 overlapping the first color light-emitting unit 21 is doped with the first color particles 51, and the lens structure 3 overlapping the second color light-emitting unit 22 is doped with the second color particles 52, where the first color is different from the second color.

In an embodiment, reference is made to FIG. 24, the first color light-emitting unit 21 is, e.g., a red light-emitting unit 2, the second color light-emitting unit 22 is, e.g., a green light-emitting unit 2, the first color particles 51 are, e.g., red particles, the second color particles 52 are, e.g., green particles. The red particles are configured to absorb light other than red light in the ambient light incident on the display panel and the ambient light reflected by the light-emitting unit 2, and then configured to emit the red light emitted by the red light-emitting unit 2. The green light particles are configured to absorb light other than green light in the ambient light incident on the display panel and the ambient light reflected by the light-emitting unit 2, and then configured to emit the green light emitted by the green light-emitting unit 2.

In an embodiment, reference is made to FIG. 24, the first color light-emitting unit 21 is, e.g., a red light-emitting unit 2, the second color light-emitting unit 22 is, e.g., a blue light-emitting unit 2, the first color particles 51 are, e.g., red particles, and the second color particles 52 are, e.g., blue particles. The red particles are configured to absorb light other than red light in the ambient light incident on the display panel and the ambient light reflected by the light-emitting unit 2, and then configured to emit the red light emitted by the red light-emitting unit 2. The blue light particles are configured to absorb light other than blue light in the ambient light incident on the display panel and the ambient light reflected by the light-emitting unit 2, and then configured to emit the blue light emitted by the blue light-emitting unit 2.

In an embodiment, reference is made to FIG. 24, the first color light-emitting unit 21 is, e.g., a green light-emitting unit 2, the second color light-emitting unit 22 is, e.g., a blue light-emitting unit 2, the first color particles 51 are, e.g., green particles, and the second color particles 52 are, e.g., blue particles. The green particles are configured to absorb light other than green light in the ambient light incident on the display panel and the ambient light reflected by the light-emitting unit 2, and then configured to emit the green light emitted by the green light-emitting unit 2. The blue light particles are configured to absorb light other than blue light in the ambient light incident on the display panel and the ambient light reflected by the light-emitting unit 2, and then configured to emit the blue light emitted by the blue light-emitting unit 2.

FIG. 25 is a schematic cross-sectional structural diagram of a display panel according to another embodiment of the present disclosure. In an embodiment, as shown in FIG. 25, when the display panel includes the first color light-emitting unit 21, the second color light-emitting unit 22 and the third color light-emitting unit 23, the first color, the second color and the third color are all different. The first color light-emitting unit 21 is, e.g., a red light-emitting unit 2, the second color light-emitting unit 22 is, e.g., a green light-emitting unit 2, and the third color light-emitting unit 23 is, e.g., a blue light-emitting unit 2. In the direction X perpendicular to the plane where the driving substrate 1 is located, the lens structure 3 overlapping the first color light-emitting unit 21 is doped with first color particles 51, the lens structure 3 overlapping the second color light-emitting unit 22 is doped with second color particles 52, the lens structure 3 overlapping the third color light-emitting unit 22 is doped with third color particles 52. The first color particles 51 are, e.g., red particles, the second color particles 52 are, e.g., green particles, and the third color particles 50 are, e.g., blue particles. The red particles are configured to absorb light other than red light in the ambient light incident on the display panel and the ambient light reflected by the light-emitting unit 2, and then configured to emit the red light emitted by the red light-emitting unit 2. The green light particles are configured to absorb light other than green light in the ambient light incident on the display panel and the ambient light reflected by the light-emitting unit 2, and then configured to emit the green light emitted by the green light-emitting unit 2. The blue light particles are configured to absorb light other than blue light in the ambient light incident on the display panel and the ambient light reflected by the light-emitting unit 2, and then configured to emit the blue light emitted by the blue light-emitting unit 2 to achieve a full-color display of the display panel. The first color particles 51, the second color particles 52 and the third color particles 50 are integrated with the lens structure 3, which simplifies the overall structure of the display panel. There is no need to separately arrange space for the first color particles 51, the second color particles 52 and the third color particles 50, which avoids the problem that the first color particles 51, the second color particles 52 and the third color particles 50 are arranged separately from the lens structure 3 and occupying too much space on the display panel, which is conducive to making the display device lighter and thinner.

FIG. 26 is a schematic cross-sectional structural diagram of a display panel according to another embodiment of the present disclosure. In an embodiment, reference is made to FIG. 26, the light-emitting unit 2 is a preset color light-emitting unit 2; the lens structure 3 includes a first lens structure 301 and a second lens structure 302; the first lens structure 301 includes color conversion particles 53. The light color converted by the color conversion particle 53 is different from the preset color.

FIG. 26 exemplarily shows that the light-emitting unit 2 includes, e.g., a first light-emitting unit 201, a second light-emitting unit 202, and a third light-emitting unit 203. In an embodiment, the first light-emitting unit 201, the second light-emitting unit 202, and the third light-emitting unit 203 may all be blue light-emitting units 2. In an embodiment, in order to ensure that the light emitting rates of the first light-emitting unit 201, the second light-emitting unit 202 and the third light-emitting unit 203 are the same or close to each other, the first lens structure 301 and the second lens structure 302 may be set to have the same curvature, refractive index and widths in the preset direction parallel to a plane where the driving substrate is located.

In order to achieve color display, in the direction X perpendicular to the plane of the driving substrate 1, the first lens structure 301 at least partially overlaps the first light-emitting unit 201, and the first lens structure 301 at least partially overlaps the second light-emitting unit 202. The first lens structure 301 at least partially overlapping the first light-emitting unit 201 includes, e.g., red conversion particles 53, which convert the blue light emitted by the blue light-emitting unit 2 into red light for emission. The first lens structure 301 at least partially overlapping the second light-emitting unit 202 includes, e.g., green conversion particles 53, which convert the blue light emitted by the blue light-emitting unit 2 into green light for emission. The second lens structure 302 that at least partially overlaps the third light-emitting unit 203 may only include, e.g., a base material structure. The blue light emitted by the third light-emitting unit 203 is condensed by the second lens structure 302 and then emitted outward as the blue light. Therefore, the preset color light is converted into different color light through arranging the color conversion particles 53 in the first lens structure 301 and then emitted, to achieve the full-color display of the display panel.

Therefore, the preset color light emitted by the preset color light-emitting unit 2 may be converted into the corresponding color light through arranging the color conversion particles 53, and the color conversion particles 53 are integrated with the lens structure 3 without the need for arranging a separate space for the color conversion particles 53, which avoids the problem that the color conversion particles 53 are arranged separately from the lens structure 3 and occupying too much space on the display panel, which is beneficial to making the display device lighter and thinner.

It should be noted that the preset color may also be other colors besides blue, which is not limited herein.

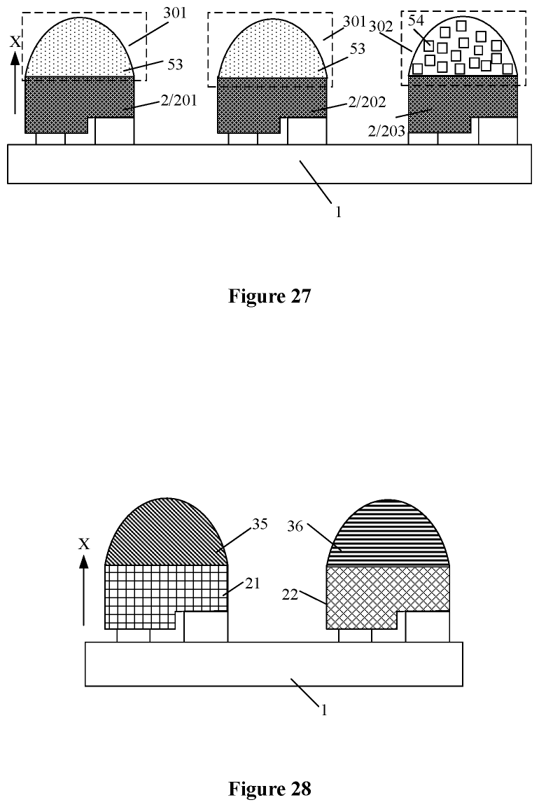

FIG. 27 is a schematic cross-sectional structural diagram of a display panel according to another embodiment of the present disclosure. In an embodiment, as shown in FIG. 27, the second lens structure 302 includes transparent particles 54.

In an embodiment, as shown in FIG. 27, the second lens structure 302 at least partially overlaps the third light-emitting unit 203 in the direction X perpendicular to the plane of the driving substrate 1, and the third light-emitting unit 203 is, e.g., the blue light-emitting unit 2. The transparent particles 54 are added to the second lens structure 302. The transparent particles 54 do not change the light color of the third light-emitting unit 203. That is, the blue light emitted by the blue light-emitting unit 2 is still blue light when it passes through the second lens structure 302. The second lens structure 302 is doped with the transparent particles 54, which do not affect the light, only the base material of the second lens structure 302 has a refractive effect on the light, and the light emitted from the third light-emitting unit 203 may be converged after passing through the second lens structure 302, to increase the light intensity in the front-view direction, thus ensuring the consistency of the process and structure of the second lens structure 302 and the first lens structure 301.

FIG. 27 shows the transparent particles 54 only for illustration. In one embodiment, shapes of the transparent particles 54 may be the same as the color conversion particles 53.

In some embodiments, as shown in FIG. 26, the second lens structure 302 may not include lens particles 54 (for clear illustration, the second lens structure 302 is not filled with patterns), and the second lens structure 302 only includes a substrate structure, the light emitted by the third light-emitting unit 203 is directly condensed by the second lens structure 302 and then emitted, which simplifies the manufacturing process of the second lens structure 302 and reduces the manufacturing cost.

FIG. 28 is a schematic cross-sectional structural diagram of a display panel according to another embodiment of the present disclosure. In an embodiment, as shown in FIG. 28, the light-emitting unit 2 includes a first color light-emitting unit 21 and a second color light-emitting unit 22, and the first color is different from the second color; the lens structure 3 includes a fifth lens 35 and a sixth lens 36. In the direction X perpendicular to the plane where the driving substrate 1 is located, the fifth lens 35 overlaps the first color light-emitting unit 21, and the sixth lens 36 overlaps the second color light-emitting unit 22. The curvature, refractive index and projection in a plane parallel to the plane of the driving substrate 1 of the fifth lens 35 and the sixth lens 36 are all the same.

In an embodiment, as shown in FIG. 28, within the difference range in the light extraction efficiency of the light-emitting units 2 of different colors at the front-view angle, in order to simplify the preparation process of the display panel and reduce the production cost of the display panel, the fifth lens 35 and the sixth lens 36 corresponding to the light-emitting units 2 with different colors may have the same design. In an embodiment, the fifth lens 35 and the sixth lens 36 may be set to have the same curvature, the fifth lens 35 and the sixth lens 36 may be set to have the same refractive index, or the fifth lens 35 and the sixth lens 36 may have the same projection in the plane parallel to the plane where the driving substrate 1 is located. The fifth lens 35 and the sixth lens 36 may also be configured to have the same curvature, refractive index and projection in a plane parallel to the plane where the driving substrate 1 is located. FIG. 28 exemplarily shows that the fifth lens 35 and the sixth lens 36 adopt the same filling pattern to represent that the curvatures, refractive indexes, and projections in a plane parallel to the plane where the driving substrate 1 is located of the fifth lens 35 and the sixth lens 36 are the same.

In an embodiment, the fifth lens 35 and the sixth lens 36 may have the same shape. The same shapes described herein may be that, e.g., the bottom surface is a flat surface and the top surface is a curved surface as shown in FIG. 28. The curvature or the refractive index is not within the same range as described in the embodiments of the present disclosure.

In an embodiment, reference is made to FIGS. 6 to 8, the display panel further includes: an encapsulation structure 4 located on the side of the lens structure 3 away from the light-emitting unit 2, and/or between the lens structure 3 and the light-emitting unit 2. The refractive index of the lens structure 3 is greater than that of the encapsulation structure 4.

In an embodiment, reference is made to FIGS. 6 to 8, the display panel further includes, e.g., the encapsulation structure 4, and the refractive index of the lens structure 3 is greater than the refractive index of the encapsulation structure 4. The lens structure 3 is exemplarily shown in FIGS. 6 to 8, e.g., the lens structure 3 is a lens with a flat lower surface and a curved or spherical upper surface.

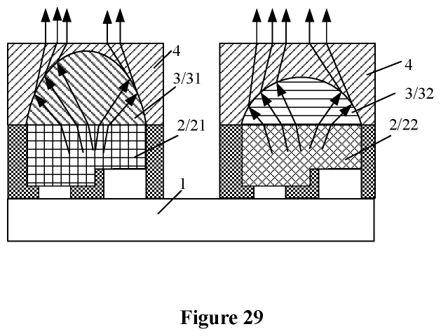

FIG. 29 is a schematic diagram of the optical path of the display panel shown in FIG. 6. Reference is made to FIG. 29, when the encapsulation structure 4 is located on the side of the lens structure 3 away from the light-emitting unit 2, the light emitted by the light-emitting unit 2 emits perpendicularly to the lower surface of the lens structure 3. Refraction occurs when the light is emitted from the lens structure 3 at different angles. The lens structure 3 plays a role in converging the light, which is emitted outward through the encapsulation structure 4 after converging the light.

Reference is made to FIG. 7, when the encapsulation structure 4 is disposed between the lens structure 3 and the light-emitting unit 2, the light emitted by the light-emitting unit 2 is emitted to the lens structure 3 through the encapsulation structure 4, and the lens structure 3 converges the light, and then the light converged emits.

Reference is made to FIG. 8, when the encapsulation structure 4 is located on the side of the lens structure 3 away from the light-emitting unit 2 and between the lens structure 3 and the light-emitting unit 2, the light emitted by the light-emitting unit 2 passes through the encapsulation structure 4 between the lens structure 3 and the light-emitting unit 2, and is incident on the lens structure 3, and the lens structure 3 condenses the light, and then emit it through the encapsulation structure 4 located on the side of the lens structure 3 away from the light-emitting unit 2.

In an embodiment, as shown in FIG. 1, the refractive index of the light-emitting unit 2 is greater than the refractive index of the lens structure 3.

Reference is made to FIG. 1, the refractive index of the light-emitting unit 2 may be set to be greater than the refractive index of the lens structure 3. After the light emitted by the light-emitting unit 2 passes through the lens structure 3 with a relatively smaller refractive index than the light-emitting unit 2, the lens structure 3 condenses the light emitted by the light-emitting unit to ensure the light extraction efficiency of the display panel at the front-view angle.

In an embodiment, reference is made to FIGS. 6 to 8, the display panel further includes: an encapsulation structure 4 located on the side of the lens structure 3 away from the light-emitting unit 2, and/or between the lens structure 3 and the light-emitting unit 2. The refractive index of the lens structure 3 ranges from 1.6 to 1.9; the refractive index of the encapsulation structure 4 ranges from 1.2 to 1.6; the refractive index of the light-emitting unit 2 is greater than 2.

In an embodiment, the refractive index of the encapsulation structure 4 may be set to be smaller than the refractive index of the lens structure 3, and the refractive index of the lens structure 3 is smaller than the refractive index of the light-emitting unit 2. When the light emitted from the light-emitting unit 2 passes through the lens structure 3 and is emitted from the encapsulation structure 4, or passes through the encapsulation structure 4 and is emitted from the lens structure, the lens structure 3 can satisfy the convergence effect of the light emitted by the light-emitting unit 2.

Therefore, the refractive indexes of the adjacent film layers of the light-emitting unit 2, i.e., the encapsulation structure 4 and the lens structure 3, are set to achieve the layout of the light emission angle, and the effect of utilizing the lens structure 3 to converge the light is achieved, which improves the light extraction efficiency of the display panel and improves the display effect of the display panel.

Herein the display panel uses a lens structure to converge the scattered light emitted by the light-emitting unit at a front-view light emission angle and emits it, which can make the light emitted by the light-emitting unit emit in the direction perpendicular to the driving substrate as much as possible after passing through the lens structure, which avoids the problem of light dispersion due to the inherent light pattern of the light-emitting unit and low light efficiency at the front-view angle, the light extraction efficiency of the display panel is improved and the display effect of the display panel is improved. There is no need to increase the driving current of the driving substrate in order to achieve front-view angle brightness, and the power consumption of the display panel can be reduced.

A display device is provided according to an embodiment of the present disclosure. The display device includes the display panel as described in any one of the above embodiments. Therefore, the display device has the features of the display panel according to the embodiments of the present disclosure, and can achieve the beneficial effects of the display panel according to the embodiments of the present disclosure. Similarities can refer to the above description of the display panel according to the embodiments of the present disclosure, which will not be described again.

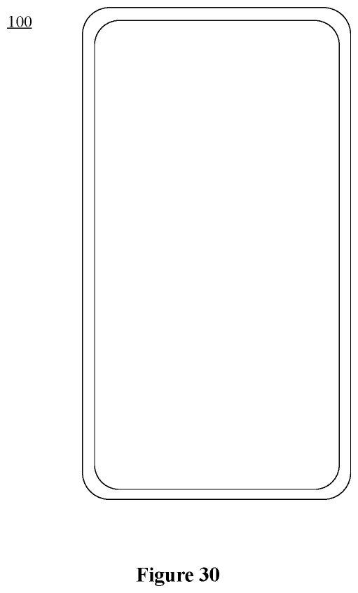

FIG. 30 is a schematic structural diagram of a display device according to an embodiment of the present disclosure. As shown in FIG. 30, a display device 100 according to an embodiment of the present disclosure includes the display panel according to any one of the above embodiments of the present disclosure. The embodiment as shown in FIG. 30 only takes a mobile phone as an example to illustrate the display device.

The display device according to the embodiments of the present disclosure can be any electronic product with a display function, including but not limited to the following categories: mobile phones, televisions, notebook computers, desktop monitors, tablet computers, digital cameras, smart phones, smart glasses, vehicle-mounted displays, medical equipment, industrial control equipment, touch interactive terminals, or the like, which are not specifically limited herein.

It should be noted that, the relationship terms such as “first”, “second” and the like are only used herein to distinguish one entity or operation from another, rather than to necessitate or imply that an actual relationship or order exists between the entities or operations. Furthermore, the terms such as “include”, “comprise” or any other variants thereof means to be non-exclusive. Therefore, a process, a method, an article or a device including a series of elements include not only the disclosed elements but also other elements that are not clearly enumerated, or further include inherent elements of the process, the method, the article or the device. Unless expressively limited, the statement “including a . . . ” does not exclude the case that other similar elements may exist in the process, the method, the article or the device other than enumerated elements.

1. A display panel, comprising:
a driving substrate;
a light-emitting unit, electrically connected to one side of the driving substrate; and
a lens structure, disposed on one side of the light-emitting unit away from the driving substrate, wherein the lens structure at least partially overlaps the light-emitting unit in a direction perpendicular to a plane where the driving substrate is located.

2. The display panel according to claim 1, wherein
the light-emitting unit comprises a first color light-emitting unit and a second color light-emitting unit that are different; and
the lens structure comprises a first lens and a second lens, in the direction perpendicular to the plane where the driving substrate is located, the first lens overlaps the first color light-emitting unit, and the second lens overlaps the second color light-emitting unit, wherein the first lens and the second lens are different in at least one of curvature, refractive index, and width in a preset direction parallel to the plane where the driving substrate is located.

3. The display panel according to claim 2, wherein
a refractive index of the first lens is smaller than a refractive index of the second lens.

4. The display panel according to claim 3, further comprising:
an encapsulation structure, at least located on one side of the lens structure away from the light-emitting unit, and/or between the lens structure and the light-emitting unit, wherein a refractive index difference between the first lens and the encapsulation structure is smaller than a refractive index difference between the second lens and the encapsulation structure.

5. The display panel according to claim 4, wherein the encapsulation structure overlapping the light-emitting unit with different colors is integrally arranged in the direction perpendicular to the plane where the driving substrate is located.

6. The display panel according to claim 2, wherein
in the direction perpendicular to the plane where the driving substrate is located, there is a first height difference between a first position and a second position of the first lens, there is a second height difference between a third position and a fourth position of the second lens, and the first height difference is greater than the second height difference, wherein the first position is located between the second position and an edge of the first lens, the third position is located between the fourth position and an edge of the second lens, in a direction parallel to the plane where the driving substrate is located, a distance between the first position and the second position is equal to a distance between the third position and the fourth position, a distance between the first position and the edge of the first lens is equal to a distance between the third position and the edge of the second lens, and/or a distance between the second position and the edge of the first lens is equal to a distance between the fourth position and the edge of the second lens.

7. The display panel according to claim 6, wherein
in the direction perpendicular to the plane where the driving substrate is located, the first lens at the second position is thicker than the second lens at the fourth position; and/or, the first lens at the first position is thicker than the second lens at the third position.

8. The display panel according to claim 2, wherein
in a plane parallel to the plane where the driving substrate is located, a projection of the first color light-emitting unit is greater than a projection of the second color light-emitting unit;
in the plane parallel to the plane where the driving substrate is located, a projection of the first lens is greater than a projection of the second lens; and/or
first lenses overlapping the first color light-emitting unit are more than second lenses overlapping the second color light-emitting unit.

9. The display panel according to claim 8, wherein
in the plane parallel to the plane where the driving substrate is located, the projection of the first lens is greater than the projection of the second lens;
in the direction perpendicular to the plane where the driving substrate is located, there is a third height difference between a fifth position and a sixth position of the first lens, and there is a fourth height difference between a seventh position and a eighth position of the second lens, and the third height difference is greater than the fourth height difference; wherein the fifth position is located between the sixth position and an edge of the first lens, and the seventh position is located between the eighth position and an edge of the second lens; in the direction parallel to the plane where the driving substrate is located, a distance between the fifth position and the sixth position is equal to a distance between the seventh position and the eighth position, a distance between the fifth position and the edge of the first lens is equal to a distance between the seventh position and the edge of the second lens, and/or a distance between the sixth position and the edge of the first lens is equal to a distance between the eighth position and the edge of the second lens.

10. The display panel according to claim 8, wherein first lenses overlapping the first color light-emitting unit are more than second lenses overlapping the second color light-emitting unit;
the first lens is equal to the second lens in curvature, and a projection of the first lens is equal to a projection of the second lens in the plane parallel to the plane where the driving substrate is located.

11. The display panel according to claim 1, further comprising:
a first area and a second area, the second area is located on at least one side of the first area, wherein the lens structure comprises a third lens and a fourth lens, in the direction perpendicular to the plane where the driving substrate is located, the third lens overlaps the first area, and the fourth lens overlaps the second area; and a focus of the fourth lens leans toward the first area.

12. The display panel according to claim 1, wherein
the lens structure comprises a base material structure and filter particles, and the filter particles are dispersed in the base material structure.

13. The display panel according to claim 12, wherein
the light-emitting unit comprises a first color light-emitting unit and a second color light-emitting unit;
the filter particles comprise at least first color particles and second color particles;
in the direction perpendicular to the plane where the driving substrate is located, the lens structure overlapping the first color light-emitting unit is doped with the first color particles, and the lens structure overlapping the second color light-emitting unit is doped with the second color particles, and the first color is different from the second color.

14. The display panel according to claim 1, wherein
the light-emitting unit is in a preset color;
the lens structure comprises a first lens structure and a second lens structure;
the first lens structure comprises color conversion particles, and a color of light converted by the color conversion particles is different from the preset color.

15. The display panel according to claim 14, wherein
the second lens structure comprises transparent particles.

16. The display panel according to claim 1, wherein
the light-emitting unit comprises a first color light-emitting unit and a second color light-emitting unit that are different;
the lens structure comprises a fifth lens and a sixth lens, in the direction perpendicular to the plane of the driving substrate is located, the fifth lens overlaps the first color light-emitting unit, and the sixth lens overlaps the second color light-emitting unit; and
the fifth lens and the sixth lens are equal in curvature, refractive index, and projection in the plane parallel to the plane where the driving substrate is located.

17. The display panel according to claim 1, further comprising:
an encapsulation structure, located on one side of the lens structure away from the light-emitting unit, and/or located between the lens structure and the light-emitting unit; and
a refractive index of the lens structure is greater than a refractive index of the encapsulation structure.

18. The display panel according to claim 1, wherein
a refractive index of the light-emitting unit is greater than a refractive index of the lens structure.

19. The display panel according to claim 1, further comprising:
an encapsulation structure located on one side of the lens structure away from the light-emitting unit, and/or located between the lens structure and the light-emitting unit;
a refractive index of the lens structure ranges from 1.6 to 1.9;
a refractive index of the encapsulation structure ranges from 1.2 to 1.6; and
a refractive index of the light-emitting unit is greater than 2.

20. A display device, comprising: a display panel, wherein the display panel comprises:
a driving substrate;
a light-emitting unit, electrically connected to one side of the driving substrate; and
a lens structure, disposed on one side of the light-emitting unit away from the driving substrate, wherein the lens structure at least partially overlaps the light-emitting unit in a direction perpendicular to a plane where the driving substrate is located.
